(19) United States
(12) Patent Application Publication
(10) Pub. No.: US 2024/0008267 A1
(43) Pub. Date: Jan. 4, 2024

(54) SEMICONDUCTOR STRUCTURE AND METHOD FOR FABRICATING SAME

(71) Applicant: CHANGXIN MEMORY TECHNOLOGIES, INC., Hefei (CN)

(72) Inventors: Youquan YU, Hefei (CN); Mingxiang SUN, Hefei (CN)

(21) Appl. No.: 18/155,061

(22) Filed: Jan. 16, 2023

Related U.S. Application Data
(63) Continuation of application No. PCT/CN2022/104874, filed on Jul. 11, 2022.

(30) Foreign Application Priority Data
Jun. 29, 2022 (CN) 202210753396.1

(51) Int. Cl. H10B 12/00

(52) U.S. Cl. CPC H10B 12/485; H10B 12/02

(57) ABSTRACT

Embodiments relate to a semiconductor structure and a method for fabricating the same. The method includes: providing a substrate; forming a bit line contact hole in the substrate; forming a bit line contact isolation layer at least covering a side wall of the bit line contact hole; forming a bit line contact layer filling up the bit line contact hole, where the bit line contact layer and the bit line contact isolation layer jointly constitute a bit line contact structure; and forming a bit line stack layer positioned on an upper surface of the bit line contact structure.

### CROSS REFERENCE TO RELATED APPLICATION

Embodiments of the present disclosure is a continuation of PCT/CN2022/104874, filed on Jul. 11, 2022, which claims priority to Chinese Patent Application No. 202210753396.1 filed to the State Patent Intellectual Property Office on Jun. 29, 2022, the entire contents of which are incorporated herein by reference.

### TECHNICAL FIELD

Embodiments of the present disclosure relate to the field of semiconductor integrated circuit manufacturing technology, and more particularly, to a semiconductor structure and a method for fabricating the same.

### BACKGROUND

During fabrication of a dynamic random access memory (DRAM), a dimension of a device structure is gradually decreasing, and a critical dimension has reduced below 20 nm. A parasitic coupling effect caused between adjacent metals is more and more obvious, and the higher a density is, the more obvious the coupling effect is, which may inevitably have a negative effect on a turn-on speed of a circuit and even yield and reliability of the circuit.

Meanwhile, in an advanced fabrication process, especially in a fabrication process for a bit line with a line width of below 20 nm, by-products generated in a dry etching or wet cleaning process and reactive chemical residues may easily cause defects such as condense due to too small critical dimension (CD), such that a middle and a bottom of the formed bit line are eroded, which finally causes failure of proper operation of the bit line, and thus yield and performance of a device is reduced.

### SUMMARY

According to various embodiments of the present disclosure, a semiconductor structure and a method for fabricating the same are provided.

According to some embodiments, one aspect of the present disclosure provides a method for fabricating a semiconductor structure, including: providing a substrate; forming a bit line contact hole in the substrate; forming a bit line contact isolation layer at least covering a side wall of the bit line contact hole; forming a bit line contact layer filling up the bit line contact hole, the bit line contact layer and the bit line contact isolation layer jointly constituting a bit line contact structure; and forming a bit line stack layer positioned on an upper surface of the bit line contact structure.

According to some embodiments, another aspect of the embodiments of the present disclosure further provides a semiconductor structure, which includes: a substrate, a bit line contact hole being provided in the substrate; a bit line contact structure comprising a bit line contact isolation layer and a bit line contact layer, where the bit line contact isolation layer at least covers a side wall of the bit line contact hole, and the bit line contact layer fills up the bit line contact hole; and a bit line stack layer positioned on an upper surface of the bit line contact structure.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIGS. 1 to 2 are schematic cross-sectional structural diagrams of structures obtained during some conventional methods;

FIG. 3 is a flowchart of a method for fabricating a semiconductor structure provided by an embodiment of the present disclosure;

FIGS. 4 to 9 are flowcharts of steps in methods for fabricating the semiconductor structure provided by different embodiments of the present disclosure; and

FIGS. 10 to 21 are schematic cross-sectional structural diagrams of structures obtained by the steps in the methods for fabricating the semiconductor structure provided by the different embodiments of the present disclosure.

### DETAILED DESCRIPTION

For ease of understanding the present disclosure, the present disclosure will be described more fully hereinafter with reference to the accompanying drawings. Embodiments of the present disclosure are presented in the accompanying drawings. However, the present disclosure may be embodied in many different forms and should not be limited to the embodiments set forth herein. Rather, these embodiments are provided such that the present disclosure will be more thorough and complete.

Unless otherwise defined, all technical and scientific terms employed herein have the same meaning as commonly understood by one of ordinary skill in the art to which the present disclosure belongs. The terms employed in the specification of the present disclosure are merely for the purpose of describing some embodiments and are not intended for limiting the present disclosure. As used herein, the term “and/or” includes any and all combinations of one or more of the associated listed items.

It should be understood that when an element or layer is referred to as being “on”, “connected to” or “coupled to” other elements or layers, it may be directly on, connected or coupled to the other elements or layers, or intervening elements or layers may be present. In contrast, when an element is referred to as being “directly on”, “directly connected to” or “directly coupled to” other elements or layers, there are no intervening elements or layers present. It should be understood that although the terms first, second, third, etc. may be employed to describe various elements, components, regions, layers and/or sections, these elements, components, regions, layers and/or sections should not be limited by these terms. These terms are only employed to distinguish one element, component, region, layer or section from another element, component, region, layer or section. Therefore, without departing from the teachings of the present disclosure, a first element, component, region, layer or section discussed below may be represented as a second element, component, region, layer or section.

Spatially relative terms such as “below”, “under”, “lower”, “beneath”, “above”, “upper” and the like may be used herein for ease of description to describe relationships between one element or feature as shown in the figures and another element(s) or feature(s). It should be understood that the spatially relative terms may be intended to encompass different orientations of the device in use or operation in addition to the orientation depicted in the figures. For example, if the device in the figures is turned over, elements or features described as “under”, “beneath” or “below” other elements would then be oriented “above” the other elements or features. Thus, the exemplary term “under”, “below” or “beneath” may encompass both an orientation of above and below. The device may be otherwise oriented (rotated 90 degrees or at other orientations) and the spatially relative descriptors used herein should be interpreted accordingly.

The terminology used herein is for the purpose of describing some embodiments only and is not intended to limit the present disclosure. As used herein, the singular forms of “a”, “one” and “said/the” are also intended to include plural forms, unless the context clearly indicates otherwise. It should also be understood that the terms “comprising” and/or “including”, when used in this specification, determine the presence of the described features, integers, steps, operations, elements and/or components, but do not preclude the presence or addition of one or more other features, integers, steps, operations, elements, components, and/or groups thereof. As used herein, the term “and/or” includes any and all combinations of related listed items.

Reference is made to FIGS. 1 to 21. It should be noted that the illustrations provided in this embodiment merely illustrate the basic idea of the present disclosure in a schematic manner. Although only the components related to the present disclosure are shown in the drawings rather than the number, shape and dimensional drawing of components in actual implementation. The form, number and proportion of each component in actual implementation may be a random change, and the component layout form thereof may be more complicated.

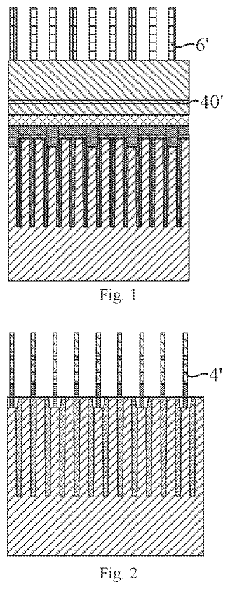

In an advanced fabrication process, such as in the fabrication process for a bit line with a line width below 20 nm, as shown in FIGS. 1 to 2, a mask layer 6′ may be formed on an upper surface of a bit line material stack layer 40′, and then a pattern defined by the mask layer 6′ is transferred to the bit line material stack layer 40′ by means of a dry etching process to form the bit line structure 40′.

By-products generated in the dry etching or wet cleaning process and reactive chemical residues may easily cause defects such as condense due to small critical dimension, such that a middle and a bottom of the formed bit line are eroded, which finally causes failure of proper operation of the bit line, and thus yield and performance of a device is reduced.

On this basis, according to some embodiments of the present disclosure, a method for fabricating a semiconductor structure is provided.

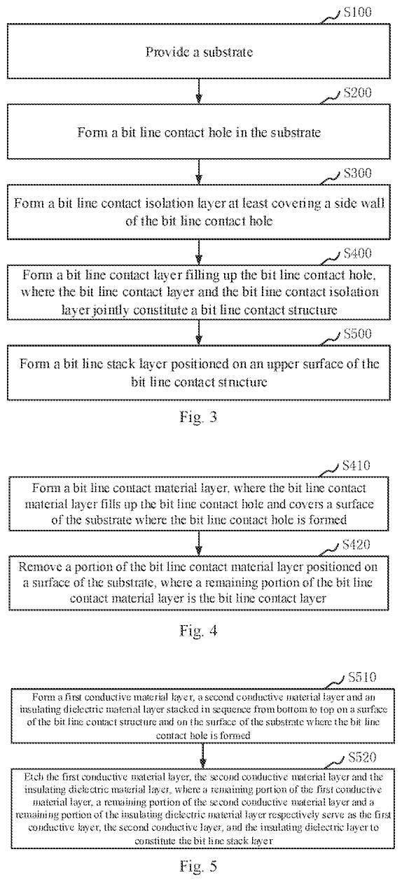

Referring to FIG. 3, in one of the embodiments, the method for fabricating the semiconductor structure may include following steps.
S100: providing a substrate.
S200: forming a bit line contact hole in the substrate.
S300: forming a bit line contact isolation layer at least covering a side wall of the bit line contact hole.
S400: forming a bit line contact layer filling up the bit line contact hole, where the bit line contact layer and the bit line contact isolation layer jointly constitute a bit line contact structure.
S500: forming a bit line stack layer positioned on an upper surface of the bit line contact structure.

In the method for fabricating the semiconductor structure provided by the above embodiments, by forming the bit line contact isolation layer covering the side wall of the bit line contact hole, adverse effects caused by a parasitic coupling effect between the bit line contact layer and the bit line stack layer can be reduced.

In addition, in the method for fabricating the semiconductor structure provided by the above embodiment, by filling up the bit line contact hole with the bit line contact layer before forming the bit line stack layer, the bit line stack layer can be effectively protected in the bit line contact isolation layer during a fabrication thereof, which can prevent a middle and a bottom of the bit line stack layer from being eroded by defects such as condense generated during the fabrication thereof, such that yield and performance of the method can be improved.

Referring to FIG. 4, in one of the embodiments, the forming the bit line contact layer in Step S400 may include following steps.
S410: forming a bit line contact material layer, where the bit line contact material layer fills up the bit line contact hole and covers a surface of the substrate where the bit line contact hole is formed.
S420: removing a portion of the bit line contact material layer positioned on a surface of the substrate, where a remaining portion of the bit line contact material layer is the bit line contact layer.

In one of the embodiments, the bit line stack layer may include a first conductive layer, a second conductive layer and an insulating dielectric layer stacked in sequence from bottom to top.

Referring to FIG. 5, in one of the embodiments, the forming the bit line contact layer in Step S400 may include following steps.
S510: forming a first conductive material layer, a second conductive material layer and an insulating dielectric material layer stacked in sequence from bottom to top on a surface of the bit line contact structure and on the surface of the substrate where the bit line contact hole is formed.
S520: etching the first conductive material layer, the second conductive material layer and the insulating dielectric material layer, where a remaining portion of the first conductive material layer, a remaining portion of the second conductive material layer and a remaining portion of the insulating dielectric material layer respectively serve as the first conductive layer, the second conductive layer and the insulating dielectric layer to constitute the bit line stack layer.

In some possible embodiments, a width of the bit line stack layer is equal to a width of a top of the bit line contact structure.

In some other possible embodiments, the width of the bit line stack layer is smaller than the width of the top of the bit line contact structure and is not smaller than a width of a top of the bit line contact layer.

According to the method for fabricating the semiconductor structure provided by the above embodiment, by forming the first conductive layer whose cross section is similar to a trapezoid, the bit line contact isolation layer may be protected. Meanwhile, the bit line stack layer obtained by the method for fabricating the semiconductor structure provided by the above embodiment has a smaller line width, such that more space can be provided to obtain a larger storage node contact hole, and thus the yield and the performance of the semiconductor structure can be further improved.

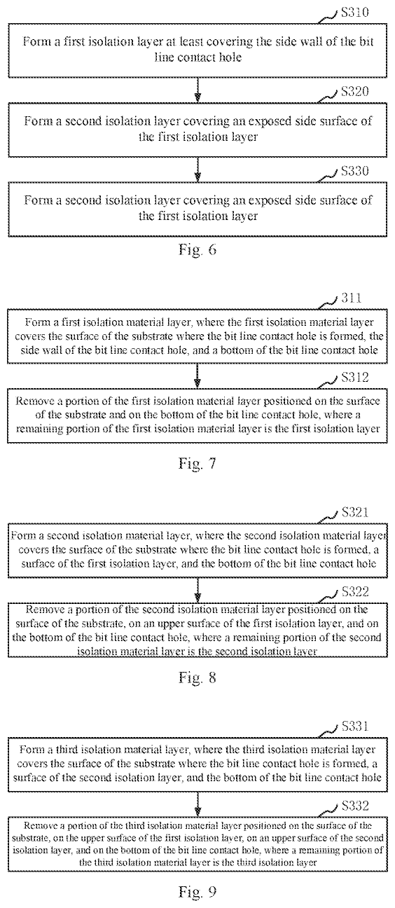

Referring to FIG. 6, in one of the embodiments, the forming the bit line contact isolation layer in Step S300 may include following steps.
S310: forming a first isolation layer at least covering the side wall of the bit line contact hole.
S320: forming a second isolation layer covering an exposed side surface of the first isolation layer.
S330: forming a third isolation layer covering an exposed side surface of the second isolation layer.

The first isolation layer, the second isolation layer and the third isolation layer constitute the bit line contact isolation layer.

Referring to FIG. 7 to FIG. 9, in one of the embodiments, the forming the first isolation layer in Step S310 may include following steps.
S311: forming a first isolation material layer, where the first isolation material layer covers the surface of the substrate where the bit line contact hole is formed, the side wall of the bit line contact hole, and a bottom of the bit line contact hole.
S312: removing a portion of the first isolation material layer positioned on the surface of the substrate and on the bottom of the bit line contact hole, where a remaining portion of the first isolation material layer is the first isolation layer.

The forming the second isolation layer in Step S320 may include following steps.
S321: forming a second isolation material layer, where the second isolation material layer covers the surface of the substrate where the bit line contact hole is formed, a surface of the first isolation layer, and the bottom of the bit line contact hole.
S322: removing a portion of the second isolation material layer positioned on the surface of the substrate, on an upper surface of the first isolation layer and on the bottom of the bit line contact hole, where a remaining portion of the second isolation material layer is the second isolation layer.

The forming the third isolation layer in Step S330 may include following steps.
S331: forming a third isolation material layer, where the third isolation material layer covers the surface of the substrate where the bit line contact hole is formed, a surface of the second isolation layer, and the bottom of the bit line contact hole.
S332: removing a portion of the third isolation material layer positioned on the surface of the substrate, on the upper surface of the first isolation layer, on an upper surface of the second isolation layer and on the bottom of the bit line contact hole, where a remaining portion of the third isolation material layer is the third isolation layer.

In one of the embodiments, a polysilicon layer is further formed on an upper surface of the substrate. In Step S520, the first conductive material layer, the second conductive material layer and the insulating dielectric material layer are etched by means of a reactant gas having a selectivity greater than or equal to 10:1 to the polysilicon layer.

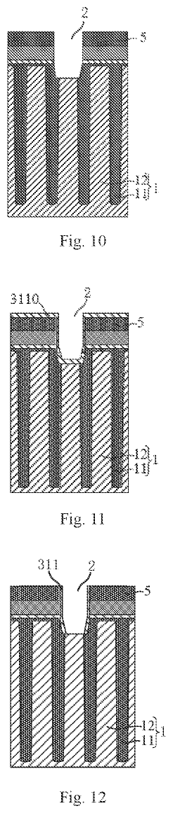

To more clearly illustrate the method in some of the above embodiments, some embodiments provided by the embodiments of the present disclosure are understood with reference to FIGS. 10 to 21 below.

In Step S100, referring to FIG. 10, a substrate 1 is provided.

In the method for fabricating the semiconductor structure in the embodiments of the present disclosure, no limitation is imposed on a material of the substrate 1. As an example, the substrate 1 may include, but is not limited to, any one or more of a silicon (Si) substrate, a sapphire substrate, a glass substrate, a silicon carbide (SiC) substrate, a gallium nitride (GaN) substrate, a gallium arsenide (GaAs) substrate, or a silicon-on-insulator (SOI) substrate, etc.

In some possible embodiments, as shown in FIG. 10, a shallow trench isolation structure 11 may be formed in the substrate 1, where the shallow trench isolation structure 11 may isolate a plurality of spaced active areas 12 in the substrate 1. As an example, the shallow trench isolation structure 11 may include a single-layer or multi-layer insulating material, such as silicon nitride (SiN), silicon oxynitride (SiON), silicon carbonitride, or other suitable insulating materials.

In Step S200, with continued reference to FIG. 10, a bit line contact hole 2 is formed in the substrate 1.

In the method for fabricating the semiconductor structure provided in the embodiment of the present disclosure, no limitation is imposed on a manner of forming the bit line contact hole 2. As an example, the bit line contact hole 2 may be formed in the substrate 1 by means of, but not limited to, the dry etching.

With continued reference to FIG. 10, as an example, the bit line contact hole 2 may be formed in the substrate 1 by: forming a patterned mask layer 5, where the patterned mask layer 103 should cover an upper surface of the substrate 1 and has an opening for defining a shape and a position of the bit line contact hole 2; and after the patterned mask layer 5 is formed, etching the substrate 1 on the basis of the patterned mask layer 5 to form the bit line contact hole 2 in the substrate 1.

It should be noted that as shown in FIG. 10, in some possible embodiments, the bit line contact hole 2 should be positioned on the active area 12, such that the bit line contact structure 3 formed in the subsequent fabrication process can be in contact with the active area 12.

In the method for fabricating the semiconductor structure provided in the embodiment of the present disclosure, no limitation is imposed on a material of the patterned mask layer 103. As an example, the patterned mask layer 103 may include, but is not limited to, a carbon (C) layer, a silicon nitride layer, an amorphous carbon layer (ACL), a silicon oxynitride layer, and a spin-on hard-mask (SOH) layer, etc.

In Step S300, referring to FIGS. 11 to 16, a bit line contact isolation layer 31 is formed. In some embodiments, the bit line contact isolation layer 31 should cover at least a side wall of the bit line contact hole 2.

In the method for fabricating the semiconductor structure provided in the embodiment of the present disclosure, no limitation is imposed on a structure of the bit line contact isolation layer 31. As an example, the bit line contact isolation layer 31 may include, but is not limited to, a first isolation layer 311, a second isolation layer 312, and a third isolation layer 313.

In one of the embodiments, Step S300 may include following steps.
S310: forming a first isolation layer 311, where the first isolation layer 311 should cover at least the side wall of the bit line contact hole 2.
S320: forming a second isolation layer 312, where the second isolation layer 312 should cover an exposed side surface of the first isolation layer 311.
S330: forming a third isolation layer 313, where the third isolation layer 313 should cover an exposed side surface of the second isolation layer 312.

As an example, referring to FIG. 11 to FIG. 12, the forming the first isolation layer 311 in Step S310 may include following steps.
S311: forming a first isolation material layer 3110, where the first isolation material layer 3110 covers the surface of the substrate 1 where the bit line contact hole 2 is formed, the side wall of the bit line contact hole 2, and a bottom of the bit line contact hole 2.
S312: removing a portion of the first isolation material layer 3110 positioned on the surface of the substrate 1 and on the bottom of the bit line contact hole 2, where a remaining portion of the first isolation material layer 3110 is the first isolation layer 311.

In the method for fabricating the semiconductor structure provided in the embodiment of the present disclosure, no limitation is imposed on a manner of removing the first isolation material layer 3110 positioned on the surface of the substrate 1 and on the bottom of the bit line contact hole 2. As an example, the first isolation material layer 3110 positioned on the surface of the substrate 1 and on the bottom of the bit line contact hole 2 may be removed by, but not limited to, a dry etching process.

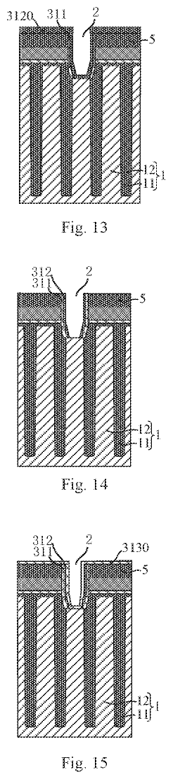

As an example, referring to FIG. 13 to FIG. 14, the forming the second isolation layer 312 in Step S320 may include following steps.
S321: forming a second isolation material layer 3120, where the second isolation material layer 3120 covers the surface of the substrate 1 where the bit line contact hole 2 is formed, a surface of the first isolation layer 311, and the bottom of the bit line contact hole 2.
S322: removing a portion of the second isolation material layer 3120 positioned on the surface of the substrate 1, on an upper surface of the first isolation layer 311 and on the bottom of the bit line contact hole 2, where a remaining portion of the second isolation material layer 3120 is the second isolation layer 312.

In the method for fabricating the semiconductor structure provided in the embodiment of the present disclosure, no limitation is imposed on a manner of removing the second isolation material layer 3120 positioned on the surface of the substrate 1, on the upper surface of the first isolation layer 311 and on the bottom of the bit line contact hole 2. As an example, the second isolation material layer 3120 positioned on the surface of the substrate 1, the upper surface of the first isolation layer 311 and the bottom of the bit line contact hole 2 may be removed by, but not limited to, a dry etching process.

As an example, referring to FIG. 15 to FIG. 16, the forming the third isolation layer 313 in Step S330 may include following steps.
S331: forming a third isolation material layer 3130, where the third isolation material layer 3130 covers the surface of the substrate 1 where the bit line contact hole 2 is formed, a surface of the second isolation layer 312, and the bottom of the bit line contact hole 2.
S332: removing a portion of the third isolation material layer 3130 positioned on the surface of the substrate 1, on the upper surface of the first isolation layer 311, on an upper surface of the second isolation layer 312 and on the bottom of the bit line contact hole 2, where a remaining portion of the third isolation material layer 3130 is the third isolation layer 313.

In the method for fabricating the semiconductor structure provided in the embodiment of the present disclosure, no limitation is imposed on a manner of removing the third isolation material layer 3130 positioned on the surface of the substrate 1, on the upper surface of the first isolation layer 311, on the upper surface of the second isolation layer 312 and on the bottom of the bit line contact hole 2. As an example, the third isolation material layer 3130 positioned on the surface of the substrate 1, on the upper surface of the first isolation layer 311, on the upper surface of the second isolation layer 312 and on the bottom of the bit line contact hole 2 may be removed by, but not limited to, a dry etching process.

In the method for fabricating the semiconductor structure provided in the embodiment of the present disclosure, no limitation is imposed on a material of the first isolation layer 311, a material of the second isolation layer 312, and a material of the third isolation layer 313. In one of the embodiments, the first isolation layer 311 and the third isolation layer 313 may each include a nitride layer; and the second isolation layer 312 may include an oxide layer. In this way, the first isolation layer 311, the second isolation layer 312 and the third isolation layer 313 may constitute the bit line contact isolation layer 31 having an N-O-N structure.

As an example, a material of the first isolation layer 311 and a material of the third isolation layer 313 may include, but are not limited to, silicon nitride or silicon oxynitride, etc.

In the method for fabricating the semiconductor structure provided in the embodiment of the present disclosure, no limitation is imposed on a material of the first isolation material layer 3110, a material of the second isolation material layer 3120, and a material of the third isolation material layer 3130. It is to be understood that the material of the first isolation material layer 3110, the material of the second isolation material layer 3120, and the material of the third isolation material layer 3130 should be adaptively selected according to the material of the first isolation layer 311, the material of the second isolation layer 312, and the material of the third isolation layer 313, respectively.

In the method for fabricating the semiconductor structure provided in the embodiment of the present disclosure, no limitation is imposed on a manner of forming the first isolation material layer 3110, the second isolation material layer 3120, and the third isolation material layer 3130. As examples, the first isolation material layer 3110 may be formed on the surface of the substrate 1, the surface of the bit line contact hole 2, the side wall of the bit line contact hole 2 and the bottom of the bit line contact hole 2 by means of, but not limited, chemical vapor deposition (CVD), physical vapor deposition (PVD), high-density plasma chemical vapor deposition (PCVD), plasma enhanced chemical vapor deposition (PECVD) or atomic layer deposition (ALD). Similarly, the second isolation material layer 3120 and the third isolation material layer 3130 may also be formed by means of the aforementioned deposition processes.

In the method for fabricating the semiconductor structure provided in the embodiment of the present disclosure, no limitation is imposed on a thickness of the first isolation layer 311, a thickness of the second isolation layer 312, and a thickness of the third isolation layer 313. As an example, the thickness of the first isolation layer 311 may be 3 nm to 5 nm. For example, the thickness of the first isolation layer 311 may be 3 nm, 4 nm, or 5 nm, etc. As an example, the thickness of the second isolation layer 312 may be 0.5 nm to 1.5 nm. For example, the thickness of the second isolation layer 312 may be 0.5 nm, 1 nm, or 1.5 nm, etc. As an example, the thickness of the third isolation layer 313 may be 8 nm to 10 nm. For example, the thickness of the third isolation layer 313 may be 8 nm, 9 nm, or 10 nm, etc.

In one of the embodiments, the thickness of the first isolation layer 311 is 4 nm, the thickness of the second isolation layer 312 is 1 nm, and the thickness of the third isolation layer 313 is 9 nm.

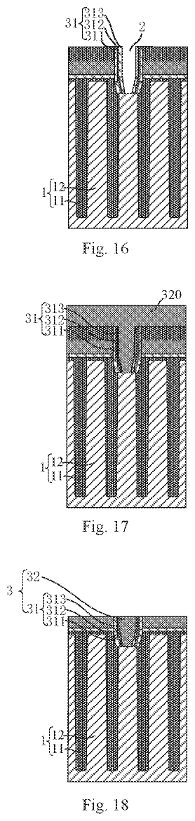

In Step S400, referring to FIGS. 17 to 18, a bit line contact layer 32 is formed. In some embodiments, the bit line contact layer 32 should fill up the bit line contact hole 2.

It is to be understood that in the method for fabricating the semiconductor structure provided by the embodiment of the present disclosure, the bit line contact layer 32 and the bit line contact isolation layer 31 together constitute the bit line contact structure 3.

In the method for fabricating the semiconductor structure provided in the embodiment of the present disclosure, no limitation is imposed on a material of the bit line contact layer 32 in Step S400. As a limitation, the material of the bit line contact layer 32 may include any one or more of polysilicon (Poly), titanium nitride (TiN), and/or tungsten (W).

In some possible embodiments, the material of the bit line contact layer 32 is the polysilicon; the deposition material of the bit line contact layer 32 may include, but not limited to, silane or disilane, and may be simultaneously doped with any one or more of boron (B), arsenic (As), phosphorus (P), or germanium (Ge).

As an example, with continued reference to FIG. 17 to FIG. 18, the forming the bit line contact layer 32 in Step S400 may include following steps.
S410: forming a bit line contact material layer 320, where the bit line contact material layer 320 should fill up the bit line contact hole 2 and cover a surface of the substrate 1 where the bit line contact hole 2 is formed.
S420: removing a portion of the bit line contact material layer 320 positioned on a surface of the substrate 1, where a remaining portion of the bit line contact material layer 320 is the bit line contact layer 32.

In the method for fabricating the semiconductor structure provided in the embodiment of the present disclosure, no limitation is imposed on a material of the bit line contact material layer 320 in Step S410. It is to be understood that the material of the bit line contact material layer 320 should be adaptively selected according to the material of the bit line contact layer 32.

In the method for fabricating the semiconductor structure provided in the embodiment of the present disclosure, no limitation is imposed on a manner of removing the bit line contact material layer 320 positioned on the surface of the substrate 1 in Step S420. As an example, the bit line contact material layer 320 positioned on the surface of the substrate 1 may be removed by means of the dry etching process or a chemical mechanical polishing (CMP) process.

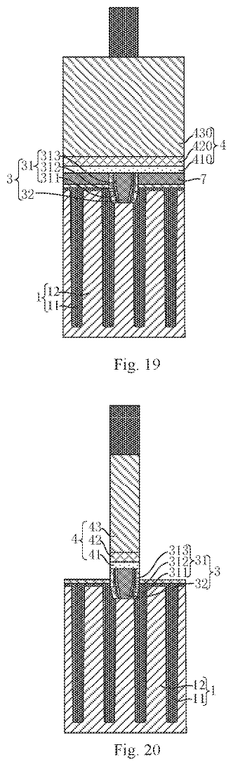

In Step S500, referring to FIGS. 19 to 20, a bit line stack layer 4 is formed. In some embodiments, the bit line stack layer 4 is positioned on the upper surface of the bit line contact structure 3.

In the method for fabricating the semiconductor structure provided in the embodiment of the present disclosure, no limitation is imposed on a structure of the bit line stack layer 4. As an example, the bit line stack layer 4 may include a first conductive layer 41, a second conductive layer 42 and an insulating dielectric layer 43 stacked in sequence from bottom to top.

In the method for fabricating the semiconductor structure provided in the embodiment of the present disclosure, no limitation is imposed on a material of the first conductive layer 41, a material of the second conductive layer 42, and a material of the insulating medium layer 43 in Step S500. As an example, the material of the first conductive layer 41 may include, but is not limited to, titanium (Ti) or titanium nitride. As an example, the material of the second conductive layer 42 may include, but is not limited to, tungsten. As an example, the material of the insulating dielectric layer 43 may include, but is not limited to, silicon nitride, silicon oxynitride, spin-on carbon (SOC), or other carbon-containing organic materials.

In one of the embodiments, the material of the second conductive layer 42 is tungsten, and the second conductive layer 42 may be defined as a metal conductive layer. On this basis, the material of the first conductive layer 41 is titanium nitride, and the first conductive layer 41 may be defined as a metal barrier layer to prevent tungsten diffusion of the second conductive layer 42.

With continued reference to FIG. 19 to FIG. 20. in one of the embodiments, Step S500 may include following steps.
S510: forming a first conductive material layer 410, a second conductive material layer 420 and an insulating dielectric material layer 430 stacked in sequence from bottom to top on a surface of the bit line contact structure 3 and on the surface of the substrate 1 where the bit line contact hole 2 is formed.
S520: etching the first conductive material layer 410, the second conductive material layer 420 and the insulating dielectric material layer 430, where a remaining portion of the first conductive material layer 410, a remaining portion of the second conductive material layer 420 and a remaining portion of the insulating dielectric material layer 430 respectively serve as the first conductive layer 41, the second conductive layer 42 and the insulating dielectric layer 43 to constitute the bit line stack layer 4.

In the method for fabricating the semiconductor structure provided in the embodiment of the present disclosure, no limitation is imposed on a material of the first conductive material layer 410, a material of the second conductive material layer 420, and a material of the insulating dielectric material layer 430 formed in Step S510. It is to be understood that the material of the first conductive material layer 410, the material of the second conductive material layer 420, and the material of the insulating dielectric material layer 430 should be adaptively selected according to the material of the first conductive layer 41, the material of the second conductive layer 42, and the material of the insulating dielectric layer 43.

In the method for fabricating the semiconductor structure provided in the embodiment of the present disclosure, no limitation is imposed on a manner of etching the first conductive material layer 410, the second conductive material layer 420 and the insulating dielectric material layer 430 to form the first conductive layer 41, the second conductive layer 42 and the insulating dielectric layer 43 in Step S520. As an example, the first conductive layer 41, the second conductive layer 42, and the insulating dielectric layer 43 may be formed by: forming a mask pattern 6 on the upper surface of the insulating dielectric material layer 430; and after forming the mask pattern 6, performing the pattern transfer process, and etching the insulating dielectric material layer 430, the second conductive material layer 420 and the first conductive material layer 410 on the basis of the mask pattern 6 to transfer the mask pattern 6 onto the first conductive material layer 410, the second conductive material layer 420 and the insulating dielectric material layer 430, to form the first conductive layer 41, the second conductive layer 42, and the insulating dielectric layer 43.

In the method for fabricating the semiconductor structure provided in the embodiment of the present disclosure, no limitation is imposed on a manner of forming the mask pattern 6. As an example, the mask pattern 6 may be formed by: forming a photoresist layer covering an upper surface of a structure obtained by means of a coating-curing process, an ink-jet printing process, or a deposition process; and performing patterning treatment such as exposure, development and etching on the aforementioned photoresist layer to obtain the mask pattern 6. The mask pattern 6 may define a shape of the bit line stack layer 4.

In the method for fabricating the semiconductor structure provided in the embodiment of the present disclosure, no limitation is imposed on a manner of forming the first conductive layer 41 whose cross section is similar to a trapezoid.

In some possible embodiments, as shown in FIG. 19, a polysilicon layer 7 is further formed on the upper surface of the substrate 1. On this basis, as an example, the first conductive layer 41 whose cross section is similar to the trapezoid may be formed by: etching the insulating dielectric material layer 430, the second conductive material layer 420 and the first conductive material layer 410 on the basis of the mask pattern 6; and when the polysilicon layer 7 is etched, continuing the subsequent etching process by using a reactant gas having a higher selectivity to the polysilicon/nitrogen (oxygen) material to perform etching, and removing the polysilicon layer 7. In this way, the bit line contact isolation layer 31 may be effectively protected. The final etching stops on the first isolation layer 311, and the bit line stack layer 4 with the middle and bottom bit line contact isolation layers 31 is reserved and formed.

As an example, the subsequent etching process may be continued by using, but not limited to, the reactant gas having the selectivity greater than or equal to 10:1 to the polysilicon/nitrogen (oxygen) material. For example, a combination of hydrobromic acid and oxygen (HBr-O₂) can reach a selectivity greater than 100:1.

In the method for fabricating the semiconductor structure provided in the embodiment of the present disclosure, no limitation is imposed on a dimension of the bit line stack layer 4.

In some possible embodiments, as shown in FIG. 20, a width of the bit line stack layer 4 may be equal to a width of a top of the bit line contact structure 3.

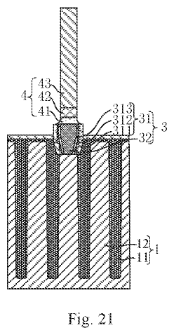

In some other possible embodiments, as shown in FIG. 21, the width of the bit line stack layer 4 may be smaller than the width of the top of the bit line contact structure 3 but should not be smaller than a width of a top of the bit line contact layer 32.

According to some embodiments, the present disclosure also provides a semiconductor structure.

With continued reference to FIG. 20, in one of the embodiments, the semiconductor structure may include the substrate 1, the bit line contact structure 3, and the bit line stack layer 4.

As shown in FIG. 20, the substrate 1 may have the bit line contact hole 2 therein. The bit line contact structure 3 may include a bit line contact isolation layer 31 and a bit line contact layer 32, where the bit line contact isolation layer 31 should at least cover the side wall of the bit line contact hole 2, and the bit line contact layer 32 should fill up the bit line contact hole 2. The bit line stack layer 4 may be positioned on the upper surface of the bit line contact structure 3.

The semiconductor structure provided by the above embodiments has the bit line contact structure 3. Because the bit line contact isolation layer 31 in the bit line contact structure 3 covers the side wall of the bit line contact hole 2, the adverse effects caused by the parasitic coupling effect between the bit line contact structure 3 and the bit line stack layer 4 can be reduced.

In addition, in the semiconductor structure provided by the above embodiments, the bit line contact layer 32 in the bit line contact structure 3 fills up the bit line contact hole 2, such that the bit line stack layer 4 positioned on the upper surface of the bit line contact structure 3 can be effectively protected in the bit line contact isolation layer 31. In this way, the middle and the bottom of the bit line stack layer 4 can be prevented from being eroded by defects such as condense. Therefore, the semiconductor structure provided by the embodiments of the present disclosure has better yield and performance.

In the semiconductor structure provided in the embodiments of the present disclosure, no limitation is imposed on the material of the substrate 1. As an example, the substrate 1 may include, but is not limited to, any one or more of a silicon substrate, a sapphire substrate, a glass substrate, a silicon carbide substrate, a gallium nitride substrate, a gallium arsenide substrate, or a silicon-on-insulator substrate, etc.

In some possible embodiments, as shown in FIG. 20, a shallow trench isolation structure 11 may be formed in the substrate 1, where the shallow trench isolation structure 11 may isolate a plurality of spaced active areas 12 in the substrate 1. In this case, the bit line contact hole 2 should be positioned on the active area 12, such that the bit line contact structure 3 can be in contact with the active area 12. As an example, the shallow trench isolation structure 11 may include a single-layer or multi-layer insulating material, such as silicon nitride (SiN), silicon oxynitride (SiON), silicon carbonitride, or other suitable insulating materials.

In the semiconductor structure provided in the embodiments of the present disclosure, no limitation is imposed on the material of the bit line contact layer 32. As a limitation, the material of the bit line contact layer 32 may include any one or more of polysilicon, titanium nitride and/or tungsten.

With continued reference to FIG. 20, in one of the embodiments, the bit line stack layer 4 may include a first conductive layer 41, a second conductive layer 42 and an insulating dielectric layer 43 stacked in sequence from bottom to top.

In the semiconductor structure provided in the embodiments of the present disclosure, no limitation is imposed on a material of the first conductive layer 41, a material of the second conductive layer 42, and a material of the insulating medium layer 43. As an example, the material of the first conductive layer 41 may include, but is not limited to, titanium (Ti) or titanium nitride. As an example, the material of the second conductive layer 42 may include, but is not limited to, tungsten. As an example, the material of the insulating dielectric layer 43 may include, but is not limited to, silicon nitride.

In the semiconductor structure provided in the embodiments of the present disclosure, no limitation is imposed on a dimension of the bit line stack layer 4.

In some possible embodiments, as shown in FIG. 20, a width of the bit line stack layer 4 may be equal to a width of a top of the bit line contact structure 3.

In some other possible embodiments, as shown in FIG. 21, the width of the bit line stack layer 4 is smaller than the width of the top of the bit line contact structure 3 and is smaller than a width of a top of the bit line contact layer 32.

The semiconductor structure provided by the above embodiments has the first conductive layer 41 whose cross section is similar to a trapezoid, which can protect the bit line contact isolation layer 31. Meanwhile, the semiconductor structure provided by the above embodiments has the bit line stack 4 with a smaller line width, such that more space can be provided to obtain a larger storage node contact hole, and thus the yield and the performance of the semiconductor structure can be further improved.

In the semiconductor structure provided in the embodiments of the present disclosure, no limitation is imposed on a structure of the bit line contact isolation layer 31. As an example, as shown in FIG. 20, the bit line contact isolation layer 31 may include, but is not limited to, a first isolation layer 311, a second isolation layer 312, and a third isolation layer 313.

In some embodiments, the first isolation layer 311 at least covers the side wall of the bit line contact hole 2; the second isolation layer 312 covers an exposed side surface of the first isolation layer 311; and the third isolation layer 313 covers an exposed side surface of the second isolation layer 312.

In the semiconductor structure provided in the embodiments of the present disclosure, no limitation is imposed on a material of the first isolation layer 311, a material of the second isolation layer 312, and a material of the third isolation layer 313. In one of the embodiments, the first isolation layer 311 and the third isolation layer 313 may each include a nitride layer; and the second isolation layer 312 may include an oxide layer. In this way, the first isolation layer 311, the second isolation layer 312 and the third isolation layer 313 may constitute the bit line contact isolation layer 31 having an N-O-N structure.

As an example, the material of the first isolation layer 311 and the material of the third isolation layer 313 may include, but are not limited to, the silicon nitride or the silicon oxynitride.

In the semiconductor structure provided in the embodiments of the present disclosure, no limitation is imposed on a thickness of the first isolation layer 311, a thickness of the second isolation layer 312, and a thickness of the third isolation layer 313. As an example, the thickness of the first isolation layer 311 may be 3 nm to 5 nm. For example, the thickness of the first isolation layer 311 may be 3 nm, 4 nm, or 5 nm, etc. As an example, the thickness of the second isolation layer 312 may be 0.5 nm to 1.5 nm. For example, the thickness of the second isolation layer 312 may be 0.5 nm, 1 nm, or 1.5 nm, etc. As an example, the thickness of the third isolation layer 313 may be 8 nm to 10 nm. For example, the thickness of the third isolation layer 313 may be 8 nm, 9 nm, or 10 nm, etc.

In one of the embodiments, the thickness of the first isolation layer 311 is 4 nm, the thickness of the second isolation layer 312 is 1 nm, and the thickness of the third isolation layer 313 is 9 nm.

It should be noted that, the methods for fabricating the semiconductor structures in the embodiments of the present disclosure may all be configured to fabricate the corresponding semiconductor structures. Therefore, the technical features between the method embodiments and the structure embodiments may be replaced and supplemented each other on the premise of no conflict, such that those skilled in the art can learn technical contents of the present disclosure.

It should be understood that unless expressly stated herein, the execution of these steps is not strictly limited in sequence, and these steps may be performed in other orders. Moreover, at least some of the steps may include a plurality of sub-steps or a plurality of stages, which are not necessarily performed at the same moment, but may be executed at different moments, and the order of execution of these sub-steps or stages is not necessarily performed sequentially, but may be performed alternately or alternately with at least a portion of the sub-steps or stages of other steps or other steps.

The embodiments in the specification are described in a progressive manner. Each embodiment is focused on difference from other embodiments. And cross reference is available for identical or similar parts among different embodiments.

Technical features of the above embodiments may be arbitrarily combined. For simplicity, all possible combinations of the technical features in the above embodiments are not described. However, as long as the combination of these technical features is not contradictory, it shall be deemed to be within the scope recorded in this specification.

The above embodiments merely express several implementations of the embodiments of the present disclosure, and descriptions thereof are relatively concrete and detailed. However, these embodiments are not thus construed as limiting the patent scope of the present disclosure. It is to be pointed out that for persons of ordinary skill in the art, some modifications and improvements may be made under the premise of not departing from a conception of the embodiments of the present disclosure, which shall be regarded as falling within the scope of protection of the embodiments of the present disclosure. Thus, patent protection scope of the embodiments of the present disclosure shall be subject to the appended claims.

What is claimed is:

1. A method for fabricating a semiconductor structure, comprising:
providing a substrate;
forming a bit line contact hole in the substrate;
forming a bit line contact isolation layer at least covering a side wall of the bit line contact hole;
forming a bit line contact layer filling up the bit line contact hole, the bit line contact layer and the bit line contact isolation layer jointly constituting a bit line contact structure; and
forming a bit line stack layer positioned on an upper surface of the bit line contact structure.

2. The method for fabricating the semiconductor structure according to claim 1, wherein the forming the bit line contact layer comprises:
forming a bit line contact material layer, the bit line contact material layer filling up the bit line contact hole and covering a surface of the substrate where the bit line contact hole is formed; and
removing a portion of the bit line contact material layer positioned on the surface of the substrate, a remaining portion of the bit line contact material layer being the bit line contact layer.

3. The method for fabricating the semiconductor structure according to claim 1, wherein the bit line stack layer comprises a first conductive layer, a second conductive layer and an insulating dielectric layer stacked in sequence from bottom to top.

4. The method for fabricating the semiconductor structure according to claim 3, wherein the forming the bit line stack layer comprises:
forming a first conductive material layer, a second conductive material layer and an insulating dielectric material layer stacked in sequence from bottom to top on a surface of the bit line contact structure and on the surface of the substrate where the bit line contact hole is formed; and
etching the first conductive material layer, the second conductive material layer and the insulating dielectric material layer, wherein a remaining portion of the first conductive material layer, a remaining portion of the second conductive material layer and a remaining portion of the insulating dielectric material layer respectively serve as the first conductive layer, the second conductive layer, and the insulating dielectric layer to constitute the bit line stack layer.

5. The method for fabricating the semiconductor structure according to claim 3, wherein a width of the bit line stack layer is equal to a width of a top of the bit line contact structure.

6. The method for fabricating the semiconductor structure according to claim 3, wherein a width of the bit line stack layer is smaller than a width of a top of the bit line contact structure and is not smaller than a width of a top of the bit line contact layer.

7. The method for fabricating the semiconductor structure according to claim 1, wherein the forming the bit line contact isolation layer comprises:
forming a first isolation layer at least covering the side wall of the bit line contact hole;
forming a second isolation layer covering an exposed side surface of the first isolation layer; and
forming a third isolation layer covering an exposed side surface of the second isolation layer;
wherein the first isolation layer, the second isolation layer and the third isolation layer constitute the bit line contact isolation layer.

8. The method for fabricating the semiconductor structure according to claim 7, wherein
the forming the first isolation layer comprises:
forming a first isolation material layer, wherein the first isolation material layer covers the surface of the substrate where the bit line contact hole is formed, the side wall of the bit line contact hole, and a bottom of the bit line contact hole; and
removing a portion of the first isolation material layer positioned on the surface of the substrate and on the bottom of the bit line contact hole, a remaining portion of the first isolation material layer being the first isolation layer;
the forming the second isolation layer comprises:
forming a second isolation material layer, wherein the second isolation material layer covers the surface of the substrate where the bit line contact hole is formed, a surface of the first isolation layer, and the bottom of the bit line contact hole; and
removing a portion of the second isolation material layer positioned on the surface of the substrate, on an upper surface of the first isolation layer and on the bottom of the bit line contact hole, a remaining portion of the second isolation material layer being the second isolation layer;
the forming the third isolation layer comprises:
forming a third isolation material layer, wherein the third isolation material layer covers the surface of the substrate where the bit line contact hole is formed, a surface of the second isolation layer, and the bottom of the bit line contact hole; and
removing a portion of the third isolation material layer positioned on the surface of the substrate, on the upper surface of the first isolation layer, on an upper surface of the second isolation layer and on the bottom of the bit line contact hole, wherein a remaining portion of the third isolation material layer is the third isolation layer.

9. The method for fabricating the semiconductor structure according to claim 8, wherein both the first isolation layer and the third isolation layer comprise a silicon nitride layer; the second isolation layer comprises a silicon oxide layer; and the bit line contact layer comprises a polysilicon layer.

10. The method for fabricating the semiconductor structure according to claim 6, wherein a polysilicon layer is further formed on an upper surface of the substrate; and
the first conductive material layer, the second conductive material layer and the insulating dielectric material layer are etched by means of a reactant gas having a selectivity greater than or equal to 10:1 to the polysilicon layer.

11. A semiconductor structure, comprising:
a substrate, a bit line contact hole being provided in the substrate;
a bit line contact structure comprising a bit line contact isolation layer and a bit line contact layer, wherein the bit line contact isolation layer at least covers a side wall of the bit line contact hole, and the bit line contact layer fills up the bit line contact hole; and
a bit line stack layer positioned on an upper surface of the bit line contact structure.

12. The semiconductor structure according to claim 11, wherein the bit line stack layer comprises a first conductive layer, a second conductive layer and a dielectric layer stacked in sequence from bottom to top.

13. The semiconductor structure according to claim 12, wherein a width of the bit line stack layer is equal to a width of a top of the bit line contact structure.

14. The semiconductor structure according to claim 12, wherein a width of the bit line stack layer is smaller than a width of a top of the bit line contact structure and is not smaller than a width of a top of the bit line contact layer.

15. The semiconductor structure according to claim 11, wherein the bit line contact isolation layer comprises:
a first isolation layer at least covering the side wall of the bit line contact hole;
a second isolation layer covering an exposed side surface of the first isolation layer; and
a third isolation layer covering an exposed side surface of the second isolation layer.

16. The semiconductor structure according to claim 15, wherein both the first isolation layer and the third isolation layer comprise a silicon nitride layer; the second isolation layer comprises a silicon oxide layer; and the bit line contact layer comprises a polysilicon layer.

17. The semiconductor structure according to claim 16, wherein a thickness of the first isolation layer is 3 nm to 5 nm; a thickness of the second isolation layer is 0.5 nm to 1.5 nm; and a thickness of the third isolation layer is 8 nm to 10 nm.
